(19) United States
(12) Patent Application Publication
(10) Pub. No.: US 2026/0237936 A1
(43) Pub. Date: Aug. 13, 2026

(54) ELECTRICAL CONNECTOR ASSEMBLY AND METHOD OF MAKING SAME

(71) Applicants: FOXCONN (KUNSHAN) COMPUTER CONNECTOR CO., LTD., Kunshan (CN); FOXCONN INTERCONNECT TECHNOLOGY LIMITED, Grand Cayman (KY)

(72) Inventors: TERRANCE F. LITTLE, fullerton, CA (US); ALEX LON AN, Danville, CA (US); AN-JEN YANG, Irvine, CA (US)

(21) Appl. No.: 19/241,716

(22) Filed: Jun. 18, 2025

Related U.S. Application Data
(60) Provisional application No. 63/757,789, filed on Feb. 12, 2025.

(51) Int. Cl. H01R 13/533; H01R 13/659; H01R 43/18

(52) U.S. Cl. CPC H01R 13/533; H01R 13/659; H01R 43/18

(57) ABSTRACT

An electrical connector assembly includes: a shielding cage forming a plurality of upper spaces, a plurality of lower spaces, and a middle channel between a upper space and a lower space, the front end of each of the upper space and the lower space having a front port for receiving a plug module; an upper cooling module disposed on the top wall of the shielding cage; and a lower cooling module disposed in the middle channels; wherein the rear end of each middle channel has an opening, and the lower cooling module is installed to the middle channels from back to front through the openings.

### CROSS REFERENCE TO RELATED APPLICATION

This application claims priority to and benefit of U.S. Provisional Patent Application No. 63/757,789, filed Feb. 12, 2025.

### BACKGROUND OF THE INVENTION

### 1. Field of the Invention

The present invention relates generally to an electrical connector assembly, and particularly to an electrical connector assembly having a liquid cooling module.

### 2. Description of Related Arts

U.S. Pat. No. 11,729,941 discloses an electrical connector assembly comprising a shielding cage, a first liquid cooling tray arranged on the top wall of the shielding cage, and a second liquid cooling tray arranged in the middle of the shielding cage. The first liquid cooling tray and the second liquid cooling tray are both installed on the housing from top to bottom, which requires the front part of the cage to be split such that the structure may not be stable.

### SUMMARY OF THE INVENTION

An electrical connector assembly comprises: a shielding cage forming a plurality of upper spaces, a plurality of lower spaces, and a respective middle channel between a corresponding upper space and a corresponding lower space, a front end of each of the upper space and the lower space having a front port for receiving a plug module; an upper cooling module disposed on the top wall of the shielding cage; and a lower cooling module disposed in the middle channels; wherein the rear end of each middle channel has an opening, and the lower cooling module is installed to the middle channels from back to front through the openings.

A method of making an electrical connector assembly, comprises the steps of: installing a plurality of vertical walls into a shielding cage having an internal space, the plurality of vertical walls dividing the internal space into a plurality of subspaces arranged in a transverse direction; installing a plurality of dividers to the plurality of subspaces, each divider dividing a corresponding subspace into an upper space, a lower space, and a middle channel between the upper space and the lower space; and installing a cooling module to the middle channels in a back-to-front direction.

An electrical connector assembly comprises: a shielding cage comprising a top wall and a pair of outer side walls extending downward from two sides of the top wall, the top wall and the pair of outer side walls cooperated to form an internal space; a divider dividing the internal space into an upper space, a lower space, and a middle channel between the upper space and the lower space, each of the upper space and the lower space having a front port for inserting different plug modules; and a cooling module disposed in the middle channels, a rear end of each middle channel being provided with an opening, the cooling module being installed in the middle channels in a back-to-front direction through the openings.

The lower cooling module being installed in the middle channels from back to front through the openings to obtain a stable structure.

### BRIEF DESCRIPTION OF DRAWINGS

FIG. 1 is a perspective view of an electrical connector assembly in according with the present invention;

FIG. 2 is another perspective view of the electrical connector assembly of FIG. 1;

FIG. 3 is an exploded view of the electrical connector assembly of FIG. 1;

FIG. 4 is another exploded view of the electrical connector assembly of FIG. 3;

FIG. 5 is an further exploded view of the electrical connector assembly of FIG. 3 without showing holder and the receptacle connector;

FIG. 6 is another exploded view of the electrical connector assembly of FIG. 5;

FIG. 7 is a further exploded view of the electrical connector assembly of FIG. 5;

FIG. 8 is another exploded view of the electrical connector assembly of FIG. 7;

FIG. 9 is another exploded view of the electrical connector assembly of FIG. 7;

FIG. 10 is further exploded view of the electrical connector assembly of FIG. 7;

FIG. 11 is further exploded view of the electrical connector assembly of FIG. 10;

FIG. 12 is an exploded view of cage;

FIG. 13 is a perspective view of cage and the lower cooling module;

FIG. 14 another perspective view of FIG. 13;

FIG. 15 a exploded view of the upper cooling module;

FIG. 16 is a cross-sectional view of the upper cooling module;

FIG. 17 is a perspective view of a varied electrical connector assembly in according with the present invention;

FIG. 18 is an exploded view of the electrical connector assembly of FIG. 17;

FIG. 19 is an exploded view of the electrical connector assembly of FIG. 18 without showing the upper cooling module;

FIG. 20 is an exploded view of the electrical connector assembly of FIG. 19 without showing the printed circuit board; and

FIG. 21 is a perspective view of the upper cooling module of FIG. 20.

### DETAILED DESCRIPTION OF THE DRAWINGS

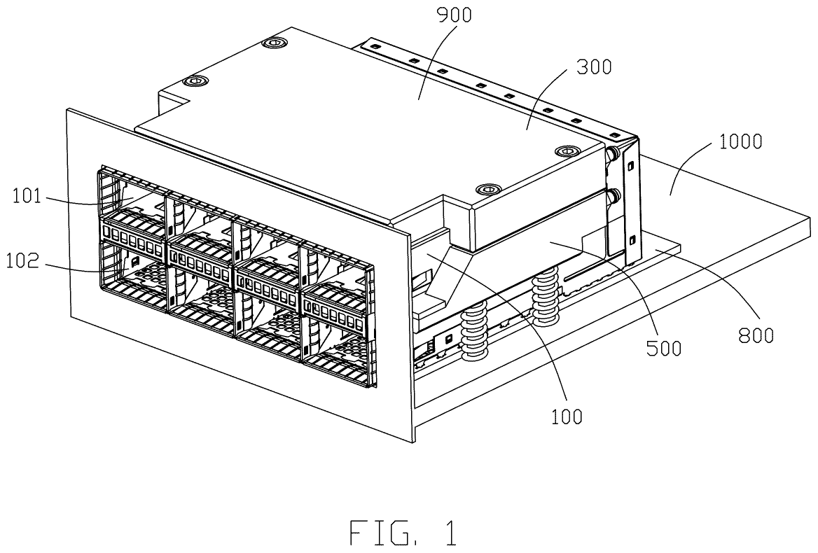

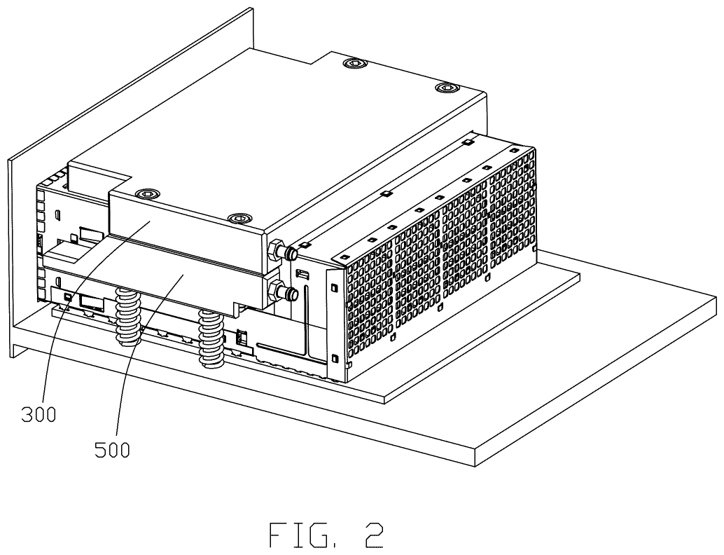

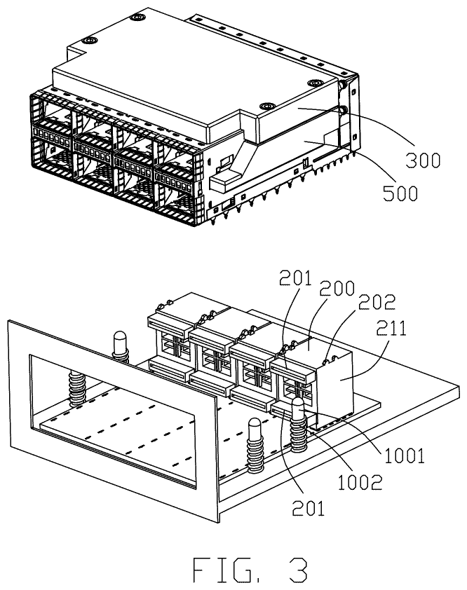

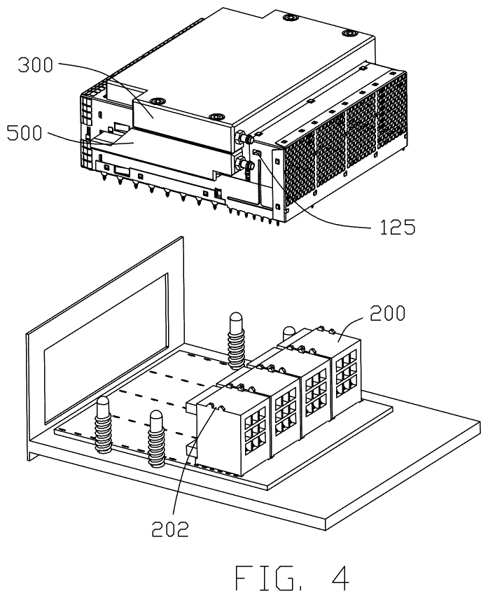

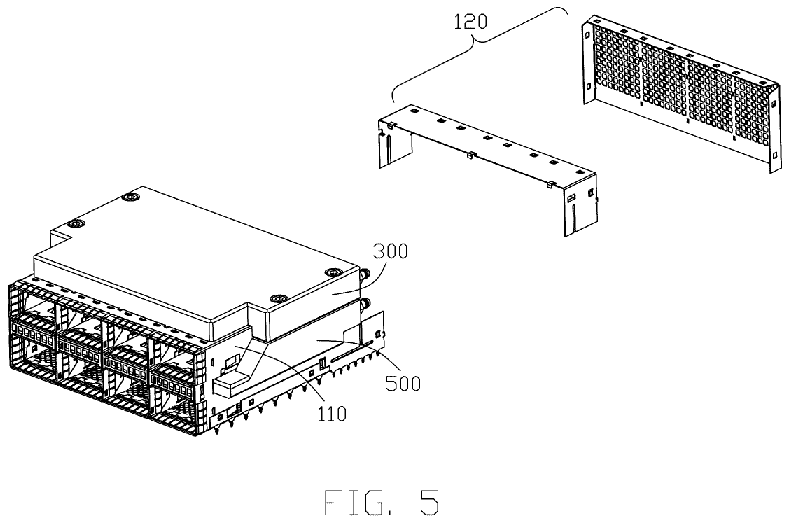

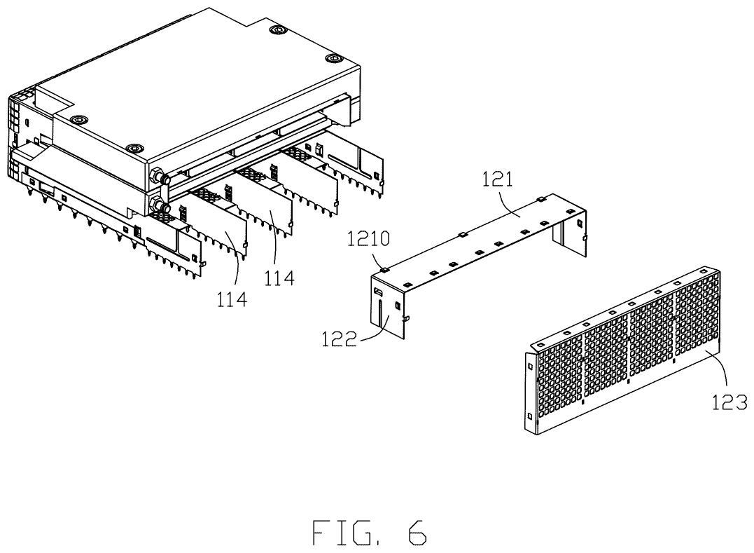

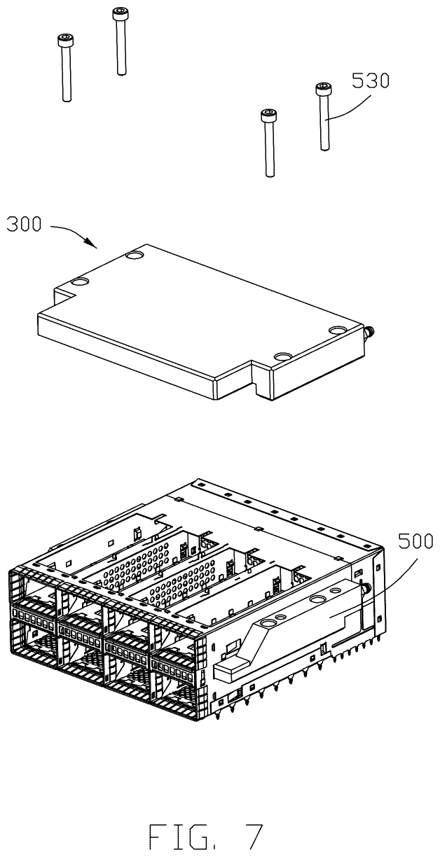

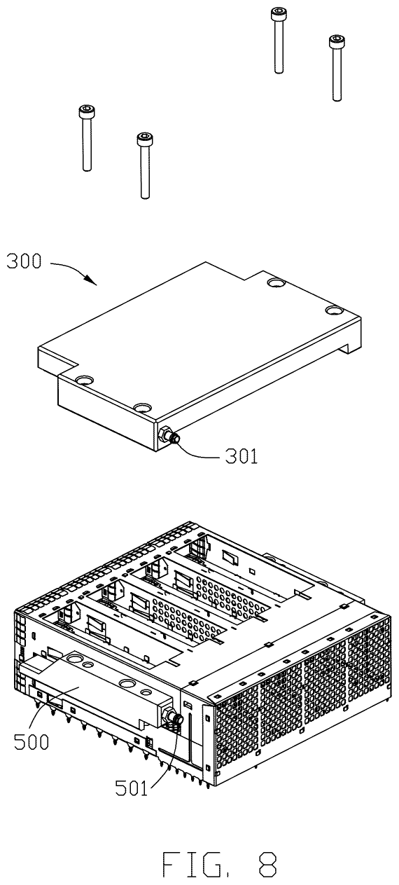

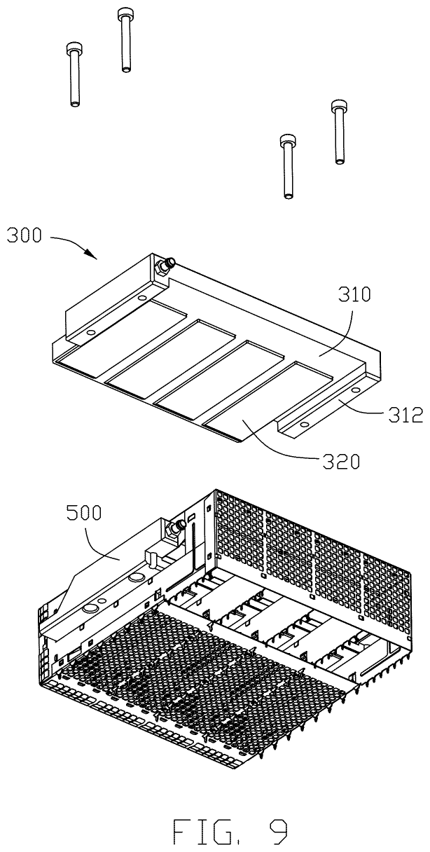

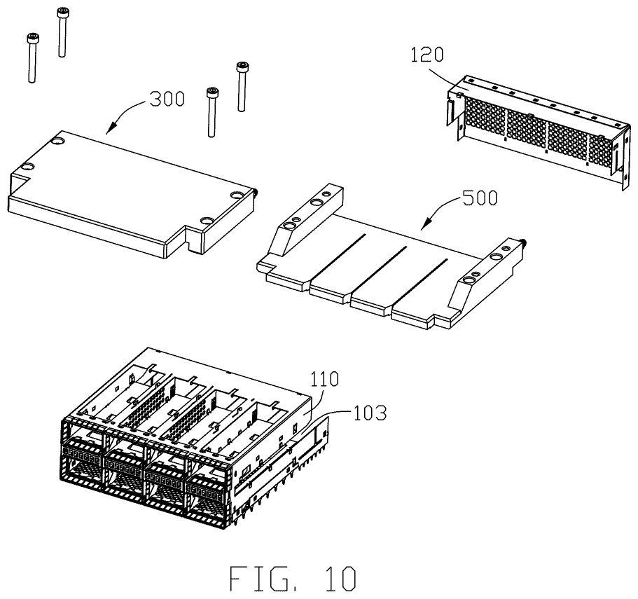

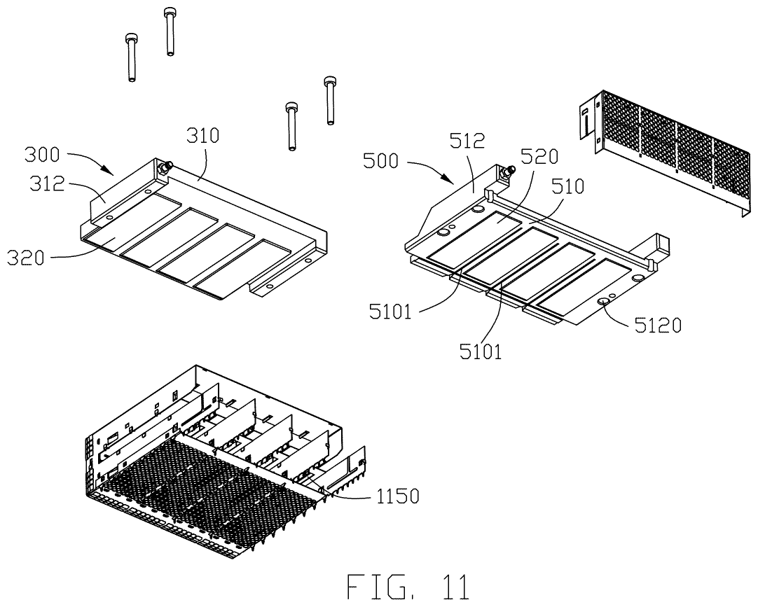

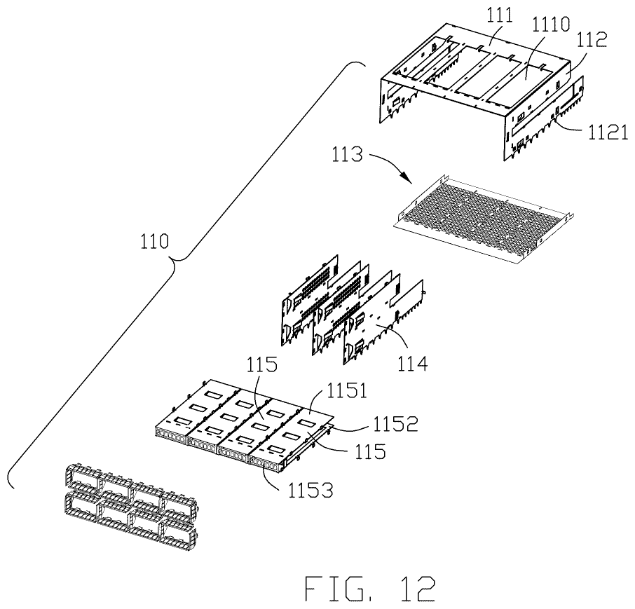

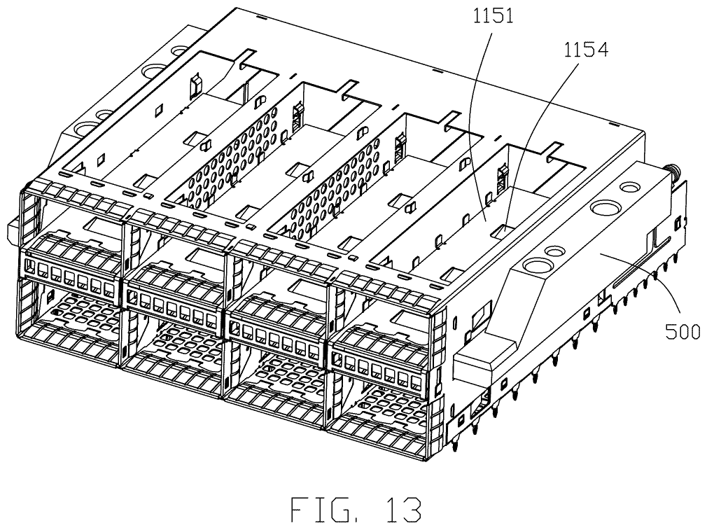

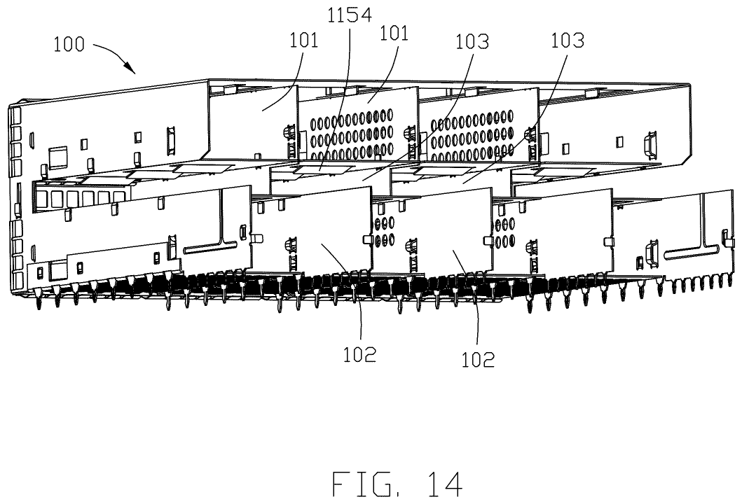

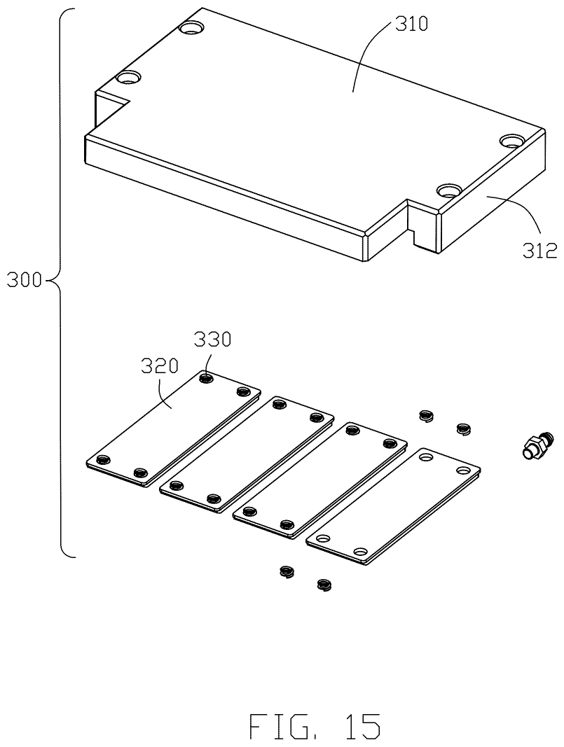

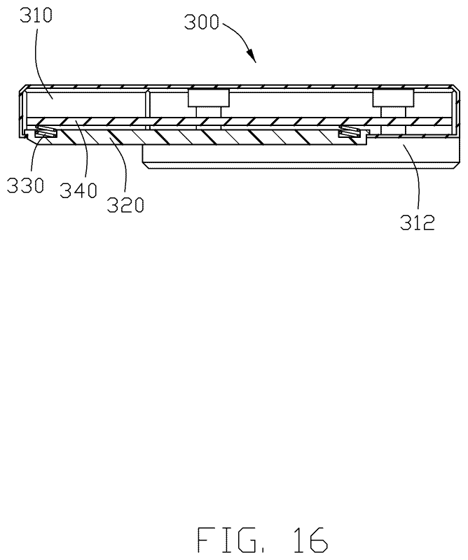

Referring to FIGS. 1-16, an electrical connector assembly 900 in accordance with the present invention is shown. The electrical connector assembly 900 can be mated with a plurality of plug module (not shown) along a front-to-back direction, and can be mounted downwardly on an external circuit board 800.

The electrical connector assembly 900 comprises an a shielding cage 100. The shielding cage 100 includes a main cage 110 and a rear cage 120, a plurality of receptacle connectors 200 received in the shielding cage 100, an upper cooling module 300, a lower cooling module 500. The main cage 110 comprises a top wall 111, a pair of outer side walls 112, a bottom wall 113, a plurality of vertical walls 114, and a plurality of divides 115. The top wall 111, the pair of outer walls 112 and the bottom wall 113 together form an internal space. The top wall 111 and the pair of outer side walls 112 are integrally formed. Each of the vertical walls 114 extends from the top wall 111 to the bottom wall 113. The plurality of vertical walls 114 dividing the internal space into a plurality of subspaces arranged in the transverse direction. Each of the divides 115 is disposed in a corresponding subspace to divide the corresponding subspace into an upper space 101, a lower space 102, and a middle channel 103 formed between the upper space 101 and the lower space 102. Each of the upper space 101 and the lower space 102 has a front port for a corresponding plug module to enter. The rear end of each middle channel 103 has an opening, and the lower cooling module 500 is installed to the middle channels 103 from back to front through the openings. The top wall 111 has a plurality of upper openings 1110 communicating with the corresponding upper spaces 101. Each of the divides 115 includes an upper wall 1151, a lower wall 1152, and a front wall 1153 connecting the upper wall 1151 and the lower wall 1152. The upper wall 1151, the lower wall 1152 and the front wall 1153 are integrally formed. The lower cooling module 500 is located in the middle channel 103. The lower wall 1152 has a lower opening 1150 communicating with the lower space 102. The upper wall 1151 of the divide 115 have spring fingers 1154 extending downwardly. Each of the spring fingers 1154 contact the upper surface of the lower cooling module 500 to push the lower cooling module 500 downward. Each of the divides 115 has at least three spring fingers 1154. Each of the vertical walls 114 extends from the top wall 111 to the bottom wall 113. The outer side wall 112 and the vertical wall 114 have mounting feet 1121 that can be mounted on the external circuit board 800.

The top wall 111 extends backward beyond the rear end of the upper cooling module 300 to facilitate installation of the rear cage 120. The bottom wall 113 does not extend backward to the rear wall 123, so that the receptacle connector 200 is installed downwardly onto the external circuit board 800. The rear cage 120 includes a rear top wall 121 matched with the top wall 111, a pair of rear outer side walls 122 matched with the pair of outer side walls 112, and a rear wall 123 connecting the rear top wall 121 and the pair of rear outer side walls 122. The rear cage 120 have features 1210 for locking with the main cage 110. In the present invention, the shielding cage 100 is a two-piece structure consisting of a main cage cage 110 and a rear cage 120, and the main cage 110 is fixed as a whole from top to bottom without being split, making the shielding cage 100 structure more stable. In this embodiment, the connector assembly has four upper ports and four lower ports. In other embodiments, any number of upper ports or lower ports may be provided, for example, only one upper port and one lower port may be provided, without the vertical wall 114; or only one port may be provided, without the vertical wall 114 and the divide 115.

The plurality receptacle connectors 200 located at the rear of the corresponding subspace. Each of the receptacle connector 200 includes an insulative housing 211 and a plurality of conductive terminals (not shown) fixed in the insulative housing 211. The insulative housing 211 includes two mating slots 201 spaced apart from each other in the vertical direction. The two mating slots 201 are aligned with the upper space 101 and the lower space 102 respectively. Each of the conductive terminal includes a contact portion extending into the corresponding mating slot 201 and a tail portion mechanically and electrically connected to the external circuit board 800. A mating tongue of the plug module can contact the conductive terminals. The receptacle connector 200 have an anti-tilt feature 202, and the rear cage 120 has a lock 125 that cooperates with the anti-tilt feature 202.

The upper cooling module 300 is capable of floating. The upper cooling module 300 includes an upper base 310, a plurality of upper contact protrusions 320 protruding downwardly from the upper base 310, and an internal elastic member 330 disposed between each of the upper contact protrusions 320 and the upper base 310. The upper base 310 cooperates with the top wall 111 of the main cage 110 and laterally spans the entire top wall 111 of the shielding cage 100. The internal elastic member 330 allows the upper contact protrusion 320 to individually float. The upper cooling module 300 further includes a pair of side walls 312 extending downwardly from the two lateral sides of the upper base 310. The pair of side walls 312 are respectively located outside the two outer side walls 112 of the main cage 110. The upper contact protrusion 320 can extend into the upper space 101 through the upper opening 1110 to contact a plug module inserted into the upper space 101. The internal elastic member 330 is a coil spring. In other embodiments, the internal elastic member 330 may also be other elastic objects. When a plug module is inserted into an upper space 101, the upper contact protrusion 320 is pushed upward by the plug module and moves relatively toward the upper base 310, at this time, the upper contact protrusion 320 squeezes the internal elastic members 330. The upper contact protrusion 320 has a groove for accommodating the spring. When the upper contact protrusion 320 moves upward, the spring can be compressed and accommodated in the groove, so that the upper contact protrusion 320 contacts the upper base 310 to transfer heat. When the plug module is pulled out, the spring helps push the upper contact protrusion 320 return to its original state. In other embodiments, the upper cooling module 300 further includes a thermal conductive material (not shown) disposed between each of the upper contact protrusions 320 and the bottom wall 340 of the upper base 310. The thermal conductive material acts as a thermal bridge between the upper contact protrusion 320 and the upper base 310. The thermal conductive material has compressibility. The thermally conductive materials can be made into thin sheets. The thermally conductive material is glued to the bottom wall 340 of the upper base 310 or the upper contact protrusion 320 by thermal glue. When the plug module is inserted, the thermal conductive material compresses and moves upward. The thermal conductive materials is made of rubber material doped with metal particle, wherein the rubber material may provide elasticity for the thermal conductive materials, and the metal particle, such as aluminum, copper and stainless steel particles and like, however, may provide improved heat conductivity for thermal conductive material. The thermal conductive material may also be made of the chemical polymer having heat conductivity and elasticity.

The lower cooling module 500 includes a lower base 510, and a plurality of lower contact protrusions 520 protruding downwardly from the bottom surface of the lower base 510. The lower contact protrusion 520 is integrally formed with the lower base 510 and and is non-floating. The lower cooling module 500 further includes a pair of side walls 512 extending upward from the two sides of the lower base 510 in the lateral direction. The lower base 510 is received in the middle channel 103 and spans all the middle channels 103 in the transverse direction. Each of the lower contact protrusions 520 protrudes into the corresponding lower space 102 through a lower opening 1150 of the lower wall 1152 of the divide 115 to contact a plug module inserted into the lower space 102. The lower base 510 has a plurality of location slots 5101 which can pass through the vertical walls 114. The location slots 5101 extends forward penetrate the front end of the lower base 510 so that the lower cooling module 500 can be installed in the middle channel 103 from the back to the front. The heat source comes from the plug module. The plug module can directly contact the cooling module to facilitate heat exchange and improve the heat dissipation effect.

The electrical connector assembly 900 further includes a holder 1000, on which there are positioning posts 1001 and helper elastic members 1002. The helper elastic member 1002 is a spring. The helper spring are sleeved on the corresponding positioning post 1001. The lower cooling module 500 further includes a pair of side walls 512 extending upward from the two sides of the lower base 510. The side wall 512 has a positioning hole 5120 for receive the upper portion of the positioning post 1001. The helper springs and the positioning posts 1001 can make the lower cooling module 500 move smoothly.

The height of the middle channel 103 is greater than the thickness of the lower base 510 to facilitate the installation of the lower cooling module 500 and allow the that the lower cooling module 500 has space to move up and down. The pair of side walls 512 of the lower cooling module 500 are located outside the pair of outer side walls 112 of the main cage 110. The upper cooling module 300 is attached and screwed into the the lower cooling module 500. Specifically, the pair of side walls 512 of the lower cooling module 500 are connected to the pair of side walls 312 of the upper cooling module 300 by screws 530. The upper cooling module 300 and the lower cooling module 500 can float up and down together relative to the shielding cage 100.

The installation steps are as follows: install the lower cooling module 500 in the shielding cage 100 from back to front; install the upper cooling module 300 on the top wall 111 of the shielding cage 100 from top to bottom; screw the upper cooling module 300 and the lower cooling module 500; and install the rear cage 120. The top wall 111 extends backward beyond the upper base 310 of the upper cooling module 300 and the rear end of the lower base 510 of the lower cooling module 500 to facilitate installation of the rear cage 120 at the rear of the main shielding cage 110. In other embodiments, the upper cooling module 300 and the lower cooling module 500 may be assembled first and then installed together from the back to the front in the shielding cage 100.

In other embodiments, the lower cooling module 500 is capable of floating like the upper cooling module 300, and there is only the lower cooling module 500.

Each of the upper cooling module 300 and the lower cooling module 500 has a coolant channel (not shown) for cooling liquid to pass through. The upper cooling module 300 is provided with a nozzle 301 connected to the coolant channel of the upper lower cooling module 300. The lower cooling module 500 is provided with a nozzle 501 connected to the coolant channel of the lower cooling module 500. The nozzle comprises an inlet nozzle and an outlet nozzle. The coolant channel is between the inlet nozzle and outlet nozzle. The coolant channels in the upper cooling module 300 and the lower cooling module 500 are interconnected. Each of the upper cooling module 300 and the lower cooling module 500 is provided with one nozzle. One of the nozzles 301 and 501 is an inlet nozzle, and the other is an outlet nozzle. The inlet nozzle and outlet nozzle are arranged on the same side. Of course, the inlet nozzle and outlet nozzle an be arranged on different sides.

In other embodiment, the coolant channel in the upper cooling module 300 is not connected to the coolant channel in the lower cooling module 500. Each of the upper cooling module 300 and the lower cooling module 500 is provided with an inlet nozzle and an outlet nozzle. The cooling liquid can be water or other cooling coolants.

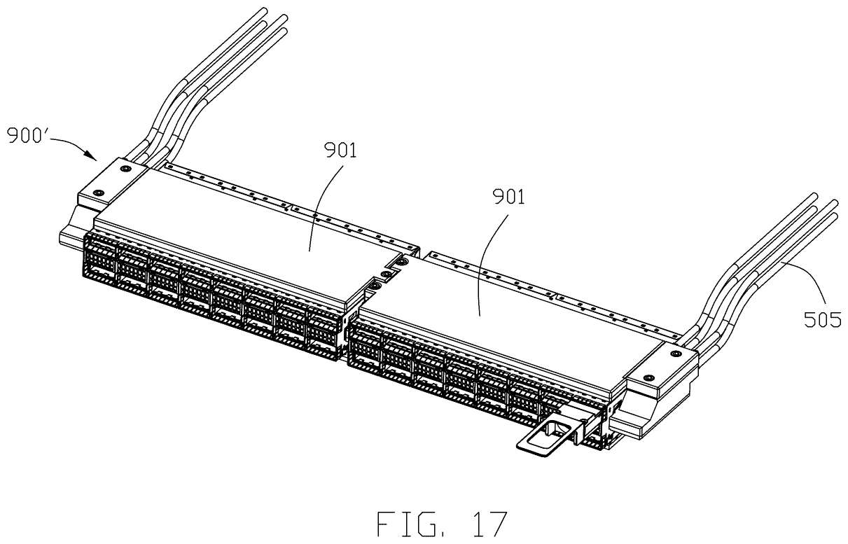

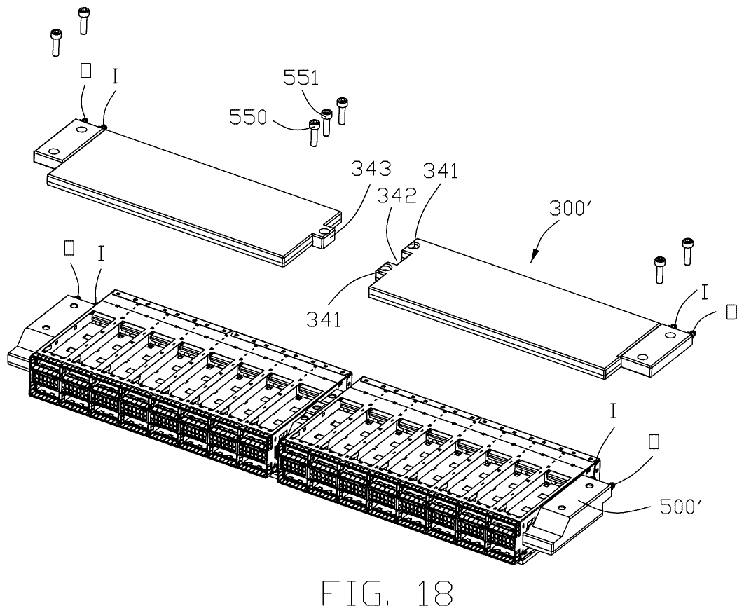

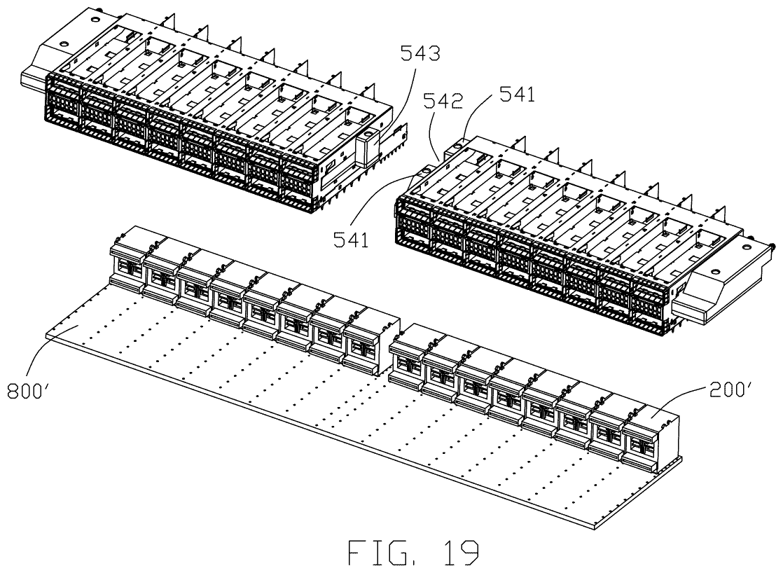

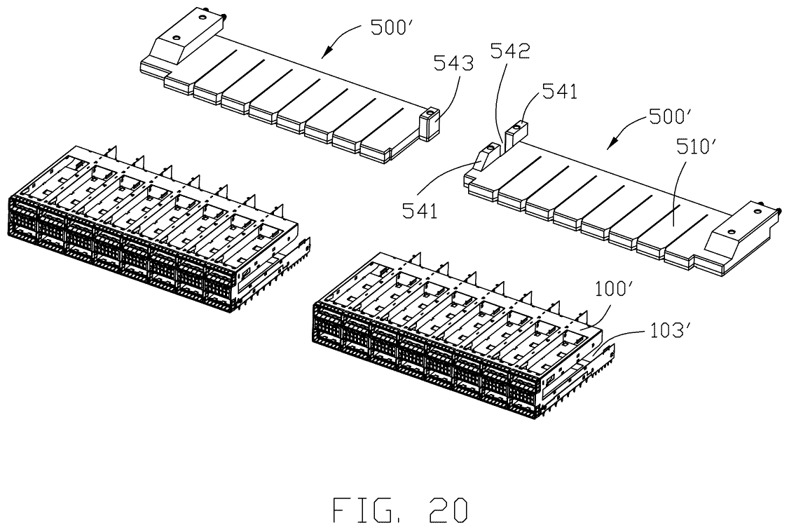

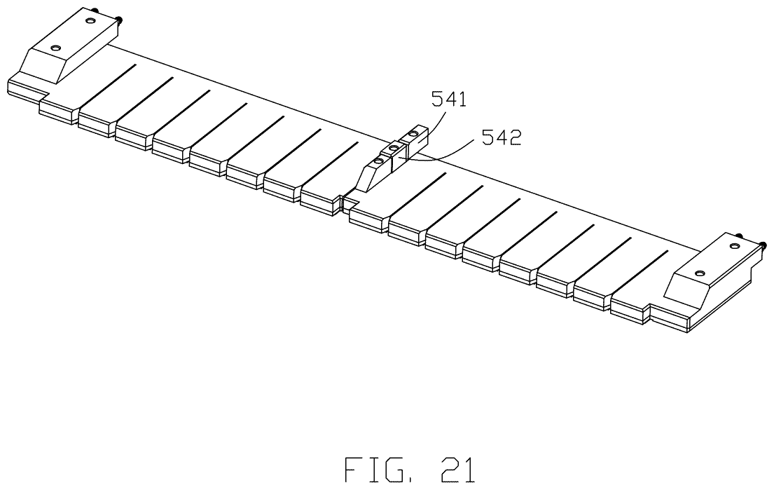

Referring to FIGS. 17-21, a varied electrical connector assembly 900′ according with the present invention is shown. The connector assembly 900′ includes two sub-connector assemblies 901 arranged in a transverse direction. each of the sub-connector assemblies 901 has eight upper ports and eight lower ports. The two sub-connector assemblies 901 are mounted on the same surface of the external circuit board 800′. Two sub-connector components 901 may also be mounted on the other surface of the circuit board 800′ and are arranged symmetrically with the two sub-connector components 901 on the same surface.

Each of the sub-connector assemblies 901 includes a shielding cage 100′, a receptacle connector 200′ received in the shielding cage 100′, an upper cooling module 300′ disposed on the top of the shielding cage 100′, and a lower cooling module 500′ disposed in the middle channel 103′. In this embodiment, the holder is omitted, and the lower cooling module 500′ is substantially the same as the upper cooling module 300 in the first embodiment. The lower cooling module 500′ includes a lower base 510′, a plurality of lower contact protrusions (not shown) extending downward from the base 510′, and an internal elastic member and a thermal conductive material disposed between the corresponding lower contact protrusions and the lower base. The lower contact protrusion can float relative to the lower base 510′. On the adjacent sides of the two sub-connector assemblies 901, one lower cooling module 500′ has two spaced-apart convex portions 541, a concave portion 542 is formed between the two convex portions 541, and the other lower cooling module 500′ has a convex portion 543 that received in the concave portion 542. Similarly, on the adjacent sides of the two sub-connector assemblies 901, one upper cooling module 300′ has two spaced-apart convex portions 341, a concave portion 342 is formed between the two convex portions 341, and the other upper cooling module 300′ has a convex portion 343 received in the concave portion 342. The convex portion 541 and the convex portion 341 are arranged on the same sub-connector assembly 901 and fixed together by screw 550. The convex portion 543 and the convex portion 343 are arranged on another sub-connector assembly 901 and fixed together by screw 551. The concave portion 542 and the convex portion 543 do not interfere with each other. The cooling module and the shielding cage 100 has no interference to receptacle connectors 200′ during installed on the external circuit board. In this embodiment, each of the upper cooling module 300′ and the lower cooling module 500′ has an inlet nozzle I and an outlet nozzle O.

The installation steps are as follows: assemble the lower cooling module 500′ in the main cage 110′; assemble the main cage 110′ and the lower cooling module 500′ on the external circuit board 800′; install the rear cage 120′; install the upper cooling module 300′ on the top of the shielding cage 100′; install fluid hoses 505.

In the present invention, the contact protrusion can float relative to the cooling module, and the cooling module can float together with the shielding cage 100, so that the plug module can better contact with the cooling module to transfer heat.

1. An electrical connector assembly comprising:
a shielding cage forming a plurality of upper spaces, a plurality of lower spaces, and a respective middle channel between a corresponding upper space and a corresponding lower space, a front end of each of the upper space and the lower space having a front port for receiving a plug module;
an upper cooling module disposed on a top wall of the shielding cage; and
a lower cooling module disposed in the middle channels; wherein
a rear end of each middle channel has an opening, and the lower cooling module is installed to the middle channels from back to front through the openings.

2. The electrical connector assembly as claimed in claim 1, wherein the shielding cage comprises:
a top wall and a pair of outer side walls extending downwardly from two sides of the top wall, the top wall and the pair of outer side walls cooperated to form an internal space;
a plurality of vertical walls dividing the internal space into a plurality of subspaces arranged in a transverse direction; and
a plurality of dividers each dividing a corresponding subspace into one upper space, one lower space, and one middle channel between the upper space and the lower space.

3. The electrical connector assembly as claimed in claim 2, wherein the lower cooling module comprises a lower base and a plurality of lower contact protrusions each protruding downward from the lower base into a corresponding lower space, and the lower base is received in the middle channel and has a plurality of location slots penetrating the front end of the lower base for the vertical walls to pass through.

4. The electrical connector assembly as claimed in claim 3, wherein a thickness of the lower base is less than a height of the middle channel.

5. The electrical connector assembly as claimed in claim 3, wherein each of the dividers comprises an upper wall, a lower wall, and a front wall connecting the upper wall and the lower wall, and the middle channel is defined between the upper wall and the lower wall.

6. The electrical connector assembly as claimed in claim 5, wherein the upper wall, the lower wall, and the front wall are integrally formed.

7. The electrical connector assembly as claimed in claim 5, wherein the lower wall has a lower opening through which a corresponding lower contact protrusion extends into a corresponding lower space, and the upper wall of each divider has a spring finger pushing the lower cooling module downward.

8. The electrical connector assembly as claimed in claim 3, further comprising a rear cage, wherein the top wall of the shielding cage extends backward beyond the rear end of the lower base of the lower cooling module to facilitate the rear cage to be attached to the rear of the shielding cage.

9. The electrical connector assembly as claimed in claim 8, wherein the rear cage is locked with the shielding cage.

10. The electrical connector assembly as claimed in claim 8, wherein the rear cage includes a rear top wall matched with the top wall, a pair of rear outer side walls matched with the pair of outer side walls, and a rear wall connecting the rear top wall and the pair of rear outer side walls.

11. The electrical connector assembly as claimed in claim 8, further comprising a plurality of receptacle connectors arranged at a rear of the corresponding subspace, each of the receptacle connectors comprises two mating slots spaced apart and aligned with the upper space and the lower space respectively, the insulative housing has an anti-tilt feature, and the rear cage has a lock cooperating with the anti-tilt feature.

12. The electrical connector assembly as claimed in claim 3, wherein the upper cooling module comprises an upper base and a plurality of upper contact protrusions each extending downward from the upper base and protruding into a corresponding upper space, and each of the upper cooling module and the lower cooling module has a coolant channel.

13. The electrical connector assembly as claimed in claim 12, wherein the lower cooling module further comprises a pair of side walls located on two sides of the lower base, the upper cooling module further comprises a pair of side walls located on two sides of the upper base, the lower base extends across the middle channels of all the dividers in the transverse direction, the pair of side walls of the upper cooling module are attached and screwed to the pair of side walls of the lower cooling module, and the upper cooling module and the lower cooling module are able to float up and down together relative to the shielding cage.

14. The electrical connector assembly as claimed in claim 2, wherein the shielding cage further comprises a bottom wall parallel to the top wall, each of the vertical walls extends from the top wall to the bottom wall and has mounting feet that can be mounted on an external circuit board, the top wall and the pair of outer side walls are integrally formed, and the shielding cage is solid in the front and non-split.

15. The electrical connector assembly as claimed in claim 1, wherein the upper cooling module is installed on the shielding cage from top to bottom and is attached to and screwed to the lower cooling module.

16. The electrical connector assembly as claimed in claim 1, wherein the upper cooling module and the lower cooling module are assembled together and installed to the shielding cage together from back to front.

17. A method of making an electrical connector assembly, comprising the steps of:
installing a plurality of vertical walls into a shielding cage having an internal space, the plurality of vertical walls dividing the internal space into a plurality of subspaces arranged in a transverse direction;
installing a plurality of dividers to the plurality of subspaces, each divider dividing a corresponding subspace into an upper space, a lower space, and a middle channel between the upper space and the lower space; and
installing a cooling module to the middle channels in a back-to-front direction.

18. The method as claimed in claim 17, wherein the step of installing comprises installing an upper cooling module on a top wall of the shielding cage from a top-to-bottom direction.

19. The method as claimed in claim 17, further comprising assembling an upper cooling module and the upper cooling module and then installing the two cooling modules in the shielding cage from the back-to-front direction.

20. An electrical connector assembly comprising:
a shielding cage comprising a top wall and a pair of outer side walls extending downward from two sides of the top wall, the top wall and the pair of outer side walls cooperated to form an internal space;
a divider dividing the internal space into an upper space, a lower space, and a middle channel between the upper space and the lower space, each of the upper space and the lower space having a front port for inserting different plug modules; and
a cooling module disposed in the middle channels, a rear end of each middle channel being provided with an opening, the cooling module being installed in the middle channels in a back-to-front direction through the openings.
